(19) United States
(12) Patent Application Publication
(10) Pub. No.: US 2023/0125049 A1
(43) Pub. Date: Apr. 20, 2023

(54) BULK ACOUSTIC WAVE FILTER

(71) Applicant: SAMSUNG ELECTRO-MECHANICS CO., LTD., Suwon-si (KR)

(72) Inventors: Hyun Min HWANG, Suwon-si (KR); Won HAN, Suwon-si (KR); Jeong Hoon RYOU, Suwon-si (KR); Jae Hyoung GIL, Suwon-si (KR); Dong Hoe KIM, Suwon-si (KR)

(73) Assignee: SAMSUNG ELECTRO-MECHANICS CO., LTD., Suwon-si (KR)

(21) Appl. No.: 17/675,058

(22) Filed: Feb. 18, 2022

(30) Foreign Application Priority Data
Oct. 19, 2021 (KR) 10-2021-0139581

(51) Int. Cl. H03H 9/56; H03H 9/205; H03H 9/13

(52) U.S. Cl. CPC H03H 9/568; H03H 9/205; H03H 9/131

(57) ABSTRACT

A bulk acoustic wave filter includes series resonators connected to a series arm, and parallel resonators connected to a parallel arm connected to the series arm. Two or more of the series resonators are disposed in parallel on the series arm, and each includes a substrate, a lower electrode on the substrate, a piezoelectric layer on the lower electrode, and an upper electrode on the piezoelectric layer, wherein, when an active region in which the lower electrode, the piezoelectric layer, and the upper electrode overlap each other is viewed from above, a centroid of the active region and a center of a rectangle defining an aspect ratio of the active region match each other, and when the active region is viewed from above, the active region has a shape of polygon symmetrical with respect to at least one axis passing through a center of the rectangle defining the aspect ratio.

### CROSS-REFERENCE TO RELATED APPLICATIONS

This application claims the benefit under 35 USC 119(a) of Korean Patent Application No. 10-2021-0139581 filed on Oct. 19, 2021, in the Korean Intellectual Property Office, the entire disclosure of which is incorporated herein by reference for all purposes.

### BACKGROUND

### 1. Field

The present disclosure relates to a bulk acoustic wave filter.

### 2. Description of the Background

RF bulk acoustic wave filters, key elements in the mobile communication market, are manufactured based on thin films of piezoelectric elements to which microelectromechanical systems (MEMS) technology is applied.

With the development of the communications market, performance improvement requirements for such devices have become stricter on a day-by-day basis, and thus, demand for bulk acoustic wave filters having a very low level of 2nd harmonic and intermodulation distortion (IMD), as well as very low insertion loss and cutoff characteristics of a sharp slope, has increased.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic wave filter includes a plurality of series resonators connected to a series arm, and a plurality of parallel resonators connected to a parallel arm connected to the series arm, wherein at least two of the plurality of series resonators are disposed in parallel on the series arm, and wherein the two series resonators disposed in parallel each includes a substrate, a lower electrode disposed on the substrate, a piezoelectric layer covering at least a portion of the lower electrode, and an upper electrode covering at least a portion of the piezoelectric layer, wherein, when an active region in which the lower electrode, the piezoelectric layer, and the upper electrode are all arranged to overlap each other is viewed from above, a centroid of the active region and a center of a rectangle defining an aspect ratio of the active region match each other, and when the active region is viewed from above, the active region has a shape of a polygon symmetrical with respect to at least one axis passing through the center of the rectangle defining the aspect ratio.

The rectangle defining the aspect ratio may be a rectangle having a largest value of the aspect ratio.

The polygon may be an N-polygon, N≥4, and N is an even number.

The aspect ratio of the active region may have a value of 5 or less.

The pair of series resonators may have the same aspect ratio of the active region.

The aspect ratio of the active region may have a value ranging from 5 to 10.

The aspect ratio of the active region may have a value of 10 or greater.

The bulk acoustic wave filter may further include a membrane layer forming a cavity together with the substrate.

The bulk acoustic wave filter may further include an etch stop portion disposed to surround the cavity.

The bulk acoustic wave filter may further include a sacrificial layer disposed outside of the etch stop portion.

The bulk acoustic wave filter may further include an insertion layer at least partially disposed between the lower electrode and the piezoelectric layer.

The bulk acoustic wave filter may further include a passivation layer disposed to expose a portion of each of the lower electrode and the upper electrode.

The bulk acoustic wave filter may further include a metal pad in contact with the portions of the lower electrode and the upper electrode exposed from the passivation layer.

In another general aspect, a bulk acoustic wave filter includes a plurality of series resonators connected to a series arm, and a plurality of parallel resonators connected to a parallel arm connected to the series arm, wherein at least two of the plurality of series resonators are disposed in parallel and spaced apart from each other, wherein the two series resonators disposed in parallel each includes a substrate, a lower electrode disposed on the substrate, a piezoelectric layer covering at least a portion of the lower electrode, and an upper electrode covering at least a portion of the piezoelectric layer, wherein, when an active region in which the lower electrode, the piezoelectric layer, and the upper electrode are all arranged to overlap each other is viewed from above, a centroid of the active region and a center of a rectangle defining an aspect ratio of the active region match each other, and when the active region is viewed from above, the active region has a shape of a polygon symmetrical with respect to at least one axis passing through the center of the rectangle defining the aspect ratio.

In another general aspect, a bulk acoustic wave filter includes a plurality of series resonators connected to a series arm, and a plurality of parallel resonators connected to a parallel arm connected to the series arm, wherein at least two of the plurality of series resonators are disposed in parallel, and wherein the two series resonators disposed in parallel each includes a bulk acoustic wave resonator having an axisymmetric polygonal shaped active region when viewed from above, and when a smallest rectangle is drawn that contains the axisymmetric polygon, a longest side of the rectangle is h, a shortest side of the rectangle is b, and an aspect ratio is h/b.

The axisymmetric polygonal shaped active region may have two lines of symmetry perpendicular to each other when viewed from above.

The bulk acoustic wave resonator may include a substrate, a lower electrode disposed on the substrate, a piezoelectric layer covering at least a portion of the lower electrode, and an upper electrode covering at least a portion of the piezoelectric layer, wherein the lower electrode, the piezoelectric layer, and the upper electrode are all arranged to overlap each other in the active region.

A centroid of the active region and a center of the rectangle may match each other.

The aspect ratio may be greater than 5 and less than 10.

The aspect ratio may be greater than or equal to 10.

The at least two of the plurality of series resonators disposed in parallel may include at least one pair connected to a beginning of the series arm, at least one pair connected to an end of the series arm, or at least one pair connected to the beginning and one pair connected to the end of the series arm.

The at least two of the plurality of series resonators disposed in parallel in each pair may be connected to each other in an anti-parallel structure.

Other features and aspects will be apparent from the following detailed description, the drawings, and the claims.

### BRIEF DESCRIPTION OF DRAWINGS

FIG. 1 is a circuit diagram illustrating a bulk acoustic wave filter according to one or more example embodiments in the present disclosure.

FIG. 2 is a schematic plan view illustrating a bulk acoustic wave resonator having an anti-parallel structure disposed in portions A and B of FIG. 1.

FIG. 3 is a schematic view illustrating an aspect ratio and a centroid of an axisymmetric polygon.

FIG. 4 is a schematic view illustrating a method of measuring a centroid.

FIG. 5 is a table illustrating a centroid of a quadrangle.

FIG. 6 is a cross-sectional view taken along line I-I′ of FIG. 2.

FIG. 7 is a cross-sectional view taken along line II-II′ of FIG. 2.

FIG. 8 is a schematic view illustrating a temperature change of a bulk acoustic wave resonator having an asymmetric structure in an active region according to the related art.

FIG. 9 is a schematic view illustrating a temperature change of a bulk acoustic wave resonator having an axisymmetric structure employed in an anti-parallel structure provided in a bulk acoustic wave filter according to an example embodiment in the present disclosure.

FIG. 10 is a schematic view illustrating a notch characteristic fs of each of a bulk acoustic wave resonator having an asymmetric structure in an active region according to the related art and a bulk acoustic wave resonator having an axisymmetric structure employed in an anti-parallel structure provided in a bulk acoustic wave filter according to an example embodiment in the present disclosure.

FIG. 11 is a schematic plan view illustrating a modified example embodiment of a bulk acoustic wave resonator having an anti-parallel structure disposed in portions A and B of FIG. 1.

FIG. 12 is a schematic plan view illustrating a modified example embodiment of a bulk acoustic wave resonator having an anti-parallel structure disposed in portions A and B of FIG. 1.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

Hereinafter, while example embodiments in the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of functions and constructions that would be well known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Herein, it is noted that use of the term “may” with respect to an example or embodiment, for example, as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. As used herein “portion” of an element may include the whole element or a part of the whole element less than the whole element.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” “lower,” and the like may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of this disclosure. Further, although the examples described herein have a variety of configurations, other configurations are possible as will be apparent after an understanding of this disclosure.

Example embodiments of the disclosure provide a bulk acoustic wave filter.

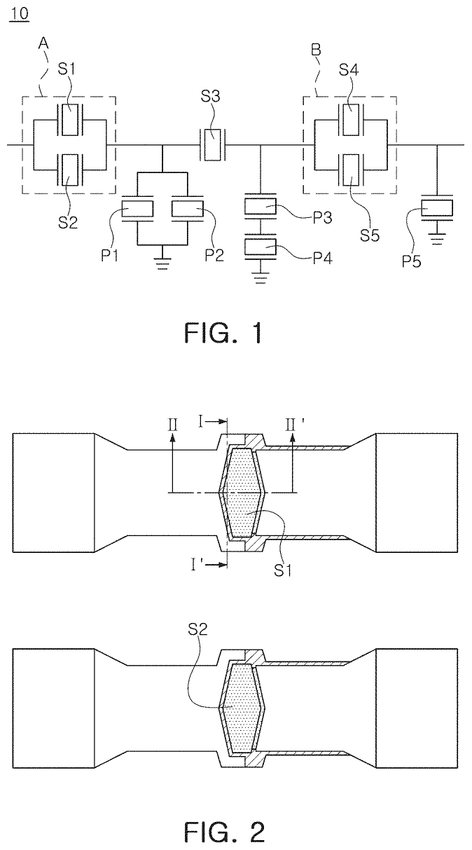

FIG. 1 is a circuit diagram illustrating a bulk acoustic wave filter according to one or more example embodiments in the present disclosure.

Referring to FIG. 1, a bulk acoustic wave filter 10 according to an example embodiment in the present disclosure may configure a bandpass filter having a certain passband by arranging a plurality of bulk acoustic wave resonators (series resonators S1 to S5, and parallel resonators P1 to P5) in series and parallel arms in a ladder form and connecting the resonators to each other. This type of filter may be generally referred to as a “ladder type filter.”

In the filter illustrated in FIG. 1, when a radio frequency (RF) signal including various frequency components is input to an input terminal In, only a desired frequency component may be output from an output terminal Out. In a configuration illustrated in FIG. 1, five bulk acoustic wave resonators S1 to S5 are arranged in the series arm and five bulk acoustic wave resonators P1 to P5 are arranged in the parallel arm. In addition, according to a filter design based on required specifications, the number of bulk acoustic wave resonators of the series arm and the parallel arm may be appropriately modified. For the bulk acoustic wave resonators P1 to P5 in the parallel arm, a frequency adjustment film formed of a material such as titanium (Ti) is formed on a film of an upper electrode, and a resonance frequency of the bulk acoustic wave resonators P1 to P5 of the parallel arm is set to be lower than a resonance frequency of the bulk acoustic wave resonators S1 to S5 of the series arm.

Meanwhile, two bulk acoustic wave resonators S1 and S2 among the bulk acoustic wave resonators S1 to S5 of the series arm are connected so that polarities of the two bulk acoustic wave resonators S1 and S2 are reversed. This structure is referred to as an anti-parallel structure hereinafter. In addition, the other two bulk acoustic wave resonators S4 and S5 among the series arm bulk acoustic wave resonators S1 to S5 also have an anti-parallel structure.

In addition, the bulk acoustic wave resonators S1, S2 and S4, S5 having an anti-parallel structure may have an axisymmetric structure.

Meanwhile, hereinafter, the bulk acoustic wave resonators S1 to S5 of the series arm are referred to as series resonators, and the bulk acoustic wave resonators P1 to P5 of the parallel arm are referred to as parallel resonators. That is, two pairs of series resonators S1 and S2 and S4 and S5 among the series resonators S1 to S5 are connected to the series arm in parallel and may be arranged in parallel with each other.

FIG. 2 is a schematic plan view illustrating a bulk acoustic wave resonator having an anti-parallel structure disposed in portions A and B of FIG. 1.

Referring to FIG. 2, in the bulk acoustic wave resonators S1 and S2 according to an example embodiment in the present disclosure, an active region may have an axisymmetric polygonal shape when viewed from above. As an example, in the bulk acoustic wave resonators S1 and S2 according to an example embodiment in the present disclosure, the active region may have an axisymmetric hexagonal shape when viewed from above. In addition, the bulk acoustic wave resonators S1 and S2 according to an example embodiment in the present disclosure may have an axisymmetric polygonal shape in which the active regions have the same aspect ratio AR when viewed from above.

Meanwhile, the active region refers to a region in which all of a lower electrode 150, a piezoelectric layer 160, and an upper electrode 170, which will be described later, overlap each other.

As illustrated in FIG. 2, when viewed from above, a centroid of the active region and a center of a rectangle defining an aspect ratio of the active region match each other, and the active region may have a shape of a polygon symmetrical with respect to at least one axis passing through the center of the rectangle defining the aspect ratio. As an example, the aspect ratio AR of the active region may have a value of 5 or less.

Here, the aspect ratio and the definition of the rectangle defining the aspect ratio are described in more detail.

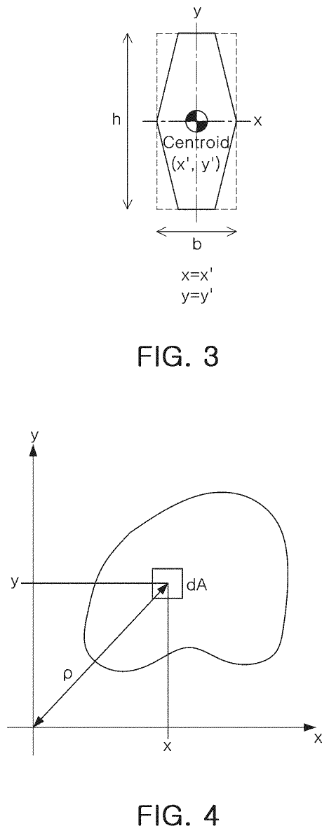

FIG. 3 is a schematic view illustrating an aspect ratio and a centroid of an axisymmetric polygon.

Referring to FIG. 3, an aspect ratio in the polygon is defined as a ratio of a minor axis to a major axis of a rectangle in contact with three or more vertices of the polygon.

That is, the aspect ratio AR is h/b ((AR)=h/b).

In other words, in the case of an axisymmetric polygon, a rectangle may be drawn in contact with the vertices as illustrated in FIG. 3. Also, as illustrated in FIG. 3, a center (x, y) of the rectangle in contact with the axisymmetric polygon coincides with a centroid (x′, y′) of the polygonal shape.

For example, when a smallest rectangle is drawn that contains the axisymmetric polygon, a longest side of the rectangle is h and a shortest side of the rectangle is b as shown in FIG. 3.

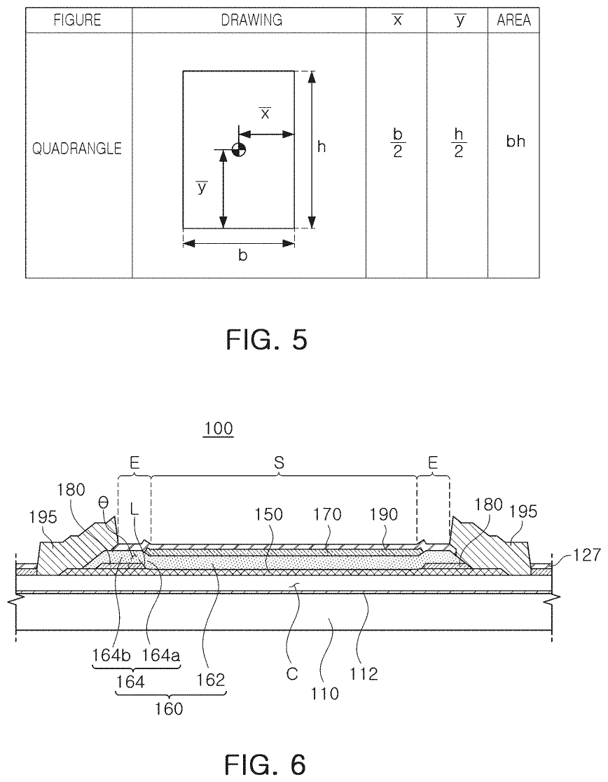

FIG. 4 is a schematic view illustrating a method for measuring a centroid, and FIG. 5 is a table illustrating a centroid of a rectangle.

Referring to FIGS. 4 and 5, first, a centroid refers to a point at which a geometrical moment area with respect to an orthogonal coordinate axis is 0 in a certain cross-section. To find a distance from the orthogonal coordinate axis to the centroid, the geometrical moment area may be divided by an area of the figure.

As illustrated in FIG. 4, for a cross section having a certain shape, a differential area dA may be considered and multiplied by a distance from the orthogonal coordinate axis to a centroid of the differential area, and then an overall area may be integrated to obtain the geometrical moment of area G.

Gₓ=∫_{A}ydA=A·y̅

G_{y}=∫_{A}xdA=A·x̅

Here, x̅ and y̅ are distances to a centroid of the cross-section from each axis.

Meanwhile, as illustrated in FIG. 5, the centroid of the rectangle among the axisymmetric polygons is the center of the rectangle. Referring to FIGS. 3 and 5 together, it can be seen that the center of the axisymmetric polygon is the centroid of the axisymmetric polygon, like the centroid of the rectangle.

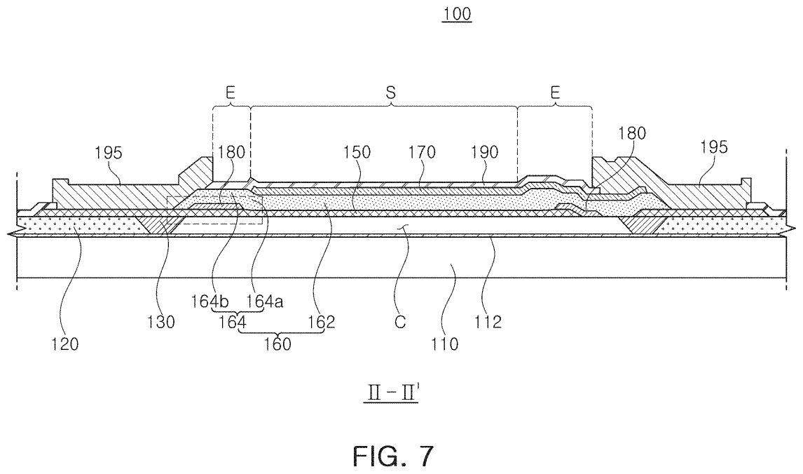

Here, as for the bulk acoustic wave resonator 100, FIG. 6 is a cross-sectional view taken along line I-I′ of FIG. 2, and FIG. 7 is a cross-sectional view taken along line II-II′ of FIG. 2.

As illustrated in FIGS. 6 and 7, as an example, the bulk acoustic wave resonators S1 and S2 according to an example embodiment in the present disclosure may include a substrate 110, a sacrificial layer 120, and an etch stop portion 130, a lower electrode 150, a piezoelectric layer 160, an upper electrode 170, an insertion layer 180, a passivation layer 190, and a metal pad 195.

The substrate 110 may be a silicon substrate. For example, a silicon wafer or a silicon on insulator (SOI) type substrate may be used as the substrate 110.

An insulating layer 112 may be formed on an upper surface of the substrate 110 and may electrically isolate the substrate 110 from a component disposed thereon. In addition, the insulating layer 112 serves to prevent the substrate 110 from being etched by an etching gas when a cavity C is formed during a manufacturing process.

In this case, the insulating layer 112 may be formed of at least one of silicon dioxide (SiO₂), silicon nitride (Si₃N₄), aluminum oxide (Al₂O₃), and aluminum nitride (AlN) and may be formed through any one of processes such as chemical vapor deposition, RF magnetron sputtering, and evaporation.

The sacrificial layer 120 may be formed on the insulating layer 112, and the cavity C and the etch stop portion 130 may be disposed on an inner side of the sacrificial layer 120. The cavity C may be formed by removing a portion of the sacrificial layer 120 during manufacturing. As described above, as the cavity C is formed on the inner side of the sacrificial layer 120, the lower electrode 150 and the like disposed on the sacrificial layer 120 may be formed flat.

The etch stop portion 130 is disposed along a boundary of the cavity C. The etch stop portion 130 serves to prevent etching from proceeding beyond the cavity region during the cavity C formation process.

The lower electrode 150 is disposed on cavity C and a portion thereof is disposed on the cavity C. In addition, the lower electrode 150 may be used as any one of an input electrode and an output electrode for inputting and outputting an electrical signal such as an RF signal.

The lower electrode 150 may be formed using, for example, a conductive material such as molybdenum (Mo) or alloys thereof. However, the present disclosure is not limited thereto, and the lower electrode 150 may be formed of a conductive material such as ruthenium (Ru), tungsten (W), iridium (Ir), platinum (Pt), copper (Cu), titanium (Ti), tantalum (Ta), nickel (Ni), chromium (Cr) or alloys thereof.

The piezoelectric layer 160 is formed to cover at least the lower electrode 150 disposed on the cavity C. Meanwhile, the piezoelectric layer 160 is a portion producing a piezoelectric effect that converts electrical energy into mechanical energy in the form of acoustic waves, and may be formed of one of aluminum nitride (AlN), zinc oxide (ZnO), and lead zirconium titanium oxide (PZT; PbZrTiO). In particular, when the piezoelectric layer 160 is formed of aluminum nitride (AlN), the piezoelectric layer 160 may further include a rare earth metal. For example, the rare earth metal may include at least one of scandium (Sc), erbium (Er), yttrium (Y), and lanthanum (La). Also, as an example, a transition metal may include at least one of titanium (Ti), zirconium (Zr), hafnium (Hf), tantalum (Ta), and niobium (Nb). In addition, magnesium (Mg), a divalent metal, may also be included.

Meanwhile, the piezoelectric layer 160 includes a piezoelectric portion 162 disposed in a flat portion S and a bent portion 164 disposed in an expansion portion E.

The piezoelectric portion 162 is a portion directly stacked on an upper surface of the lower electrode 150. Accordingly, the piezoelectric portion 162 is interposed between the lower electrode 150 and the upper electrode 170 to be flat together with the lower electrode 150 and the upper electrode 170.

The bent portion 164 may be defined as a region extending outwardly from the piezoelectric portion 162 and positioned within the expansion portion E.

The bent portion 164 is disposed on the insertion layer 180 to be described later and is formed to rise along a shape of the insertion layer 180. Accordingly, the piezoelectric layer 160 is bent at a boundary between the piezoelectric portion 162 and the bent portion 164, and the bent portion 164 rises to correspond to the thickness and shape of the insertion layer 180.

The bent portion 164 may be divided into an inclined portion 164a and an extended portion 164b.

The inclined portion 164a refers to a portion formed to be inclined along an inclined surface L of the insertion layer 180 to be described later. Also, the extended portion 164b refers to a portion extending outwardly from the inclined portion 164a.

The inclined portion 164a may be formed parallel to the inclined surface L of the insertion layer 180, and an inclination angle of the inclined portion 164a may be formed to be the same as an inclination angle θ of the inclined surface L of the insertion layer 180.

The upper electrode 170 is formed to cover at least the piezoelectric layer 160 disposed on the cavity C. The upper electrode 170 may be used as any one of an input electrode and an output electrode for inputting and outputting an electrical signal such as an RF signal. That is, when the lower electrode 150 is used as an input electrode, the upper electrode 170 may be used as an output electrode, and when the lower electrode 150 is used as an output electrode, the upper electrode 170 may be used as an input electrode.

The upper electrode 170 may be formed using, for example, a conductive material such as molybdenum (Mo) or alloys thereof. However, the present disclosure is not limited thereto, and the upper electrode 170 may include ruthenium (Ru), tungsten (W), iridium (Ir), platinum (Pt), copper (Cu), titanium (Ti), tantalum (Ta), nickel (Ni), chromium (Cr) or alloys thereof.

Meanwhile, the active region refers to a region in which the lower electrode 150, the piezoelectric layer 160, and the upper electrode 170 all overlap.

The insertion layer 180 is disposed between the lower electrode 150 and the piezoelectric layer 160. The insertion layer 180 may be formed of a dielectric such as silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), aluminum oxide (Al₂O₃), titanium oxide (TiO₂), or zinc oxide (ZnO), but is formed of a material different from that of the piezoelectric layer 160.

In addition, at least a portion of the insertion layer 180 is disposed between the piezoelectric layer 160 and the lower electrode 150. As an example, the insertion layer 180 may have a ring shape.

The passivation layer 190 is formed in a region excluding a portion of the lower electrode 150 and the upper electrode 170. Meanwhile, the passivation layer 190 serves to prevent the upper electrode 170 and the lower electrode 150 from being damaged during the process.

Meanwhile, as the passivation layer 190, a dielectric layer including any one of materials such as silicon nitride (Si₃N₄), silicon oxide (SiO₂), magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), and zinc oxide (ZnO) may be used.

The metal pad 195 is formed on portions of the lower electrode 150 and the upper electrode 170 in which the passivation layer 190 is not formed. As an example, the metal pad 195 may be formed of a material such as gold (Au), a gold-tin (Au—Sn) alloy, copper (Cu), a copper-tin (Cu—Sn) alloy, aluminum (Al), or an aluminum alloy. For example, the aluminum alloy may be an aluminum-germanium (Al—Ge) alloy.

Referring back to FIG. 2, the bulk acoustic wave resonators S1 and S2 according to an example embodiment in the present disclosure have an axisymmetric hexagonal shape in which the active regions have the same aspect ratio (AR) when viewed from above. Accordingly, a heat dissipation effect is improved to suppress the amount of movement of a notch fs due to power, thereby reducing the 2nd harmonic and IMD peak.

In detail, the 2nd harmonic and IMD may be canceled out by connecting the two resonators such that polarities thereof are reversed with an anti-parallel structure. That is, when the polarities of the piezoelectric layers 160 are opposite to each other, an input signal of f0 passes as it is, but a signal of 2f0 is canceled out to be removed. For this reason, the anti-parallel structure is generally used at a last stage of the bulk acoustic wave filter for the purpose of reducing 2nd harmonic and IMD. However, 2nd harmonic and IMD peak occur at a resonance frequency. The cause of this is that resonance frequencies of the two resonators are mismatched, so they cannot cancel each other out and 2nd harmonic and IMD peak occur. The resonance frequency mismatch of the resonators may be caused by a dispersion between resonance periods and a resonance frequency shift due to power imbalance when power is applied. In particular, power imbalance occurs between the two resonators because the same power is not applied to the two resonators when power is applied. For this reason, a lot of power is applied to one resonator out of the two, and this causes a temperature of only one resonator to rise rapidly. Therefore, the frequency of the resonator with a high temperature rises more and the 2nd harmonic and IMD peak at the resonance frequency are larger.

However, the bulk acoustic wave resonators S1 and S2 according to an example embodiment in the present disclosure have an axisymmetric hexagonal shape in which the active regions have the same aspect ratio (AR) when viewed from above. Thus, a heat dissipation effect is improved to suppress the amount of movement of the notch fs due to power, thereby reducing the 2nd harmonic and IMD peak.

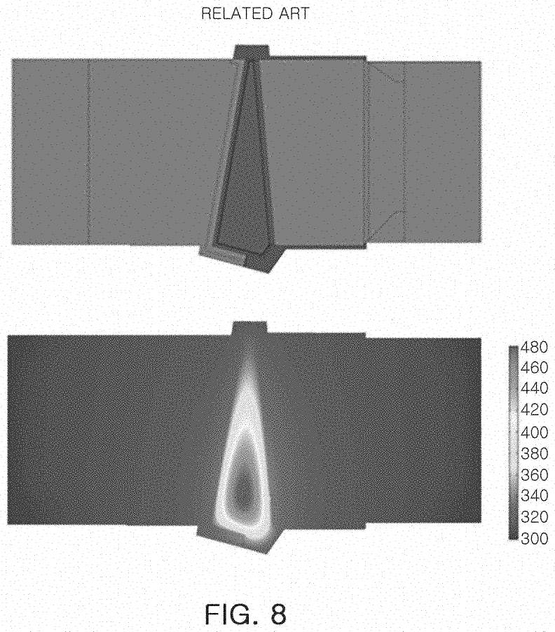

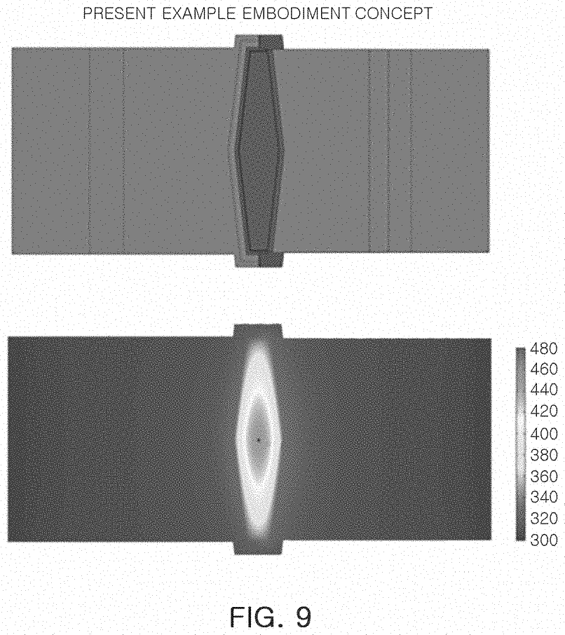

That is, as illustrated in FIGS. 8 and 9, it can be seen that, when the same power is applied to the bulk acoustic wave resonators S1 and S2 according to an example embodiment in the present disclosure compared to the related art, a temperature is reduced by 18%. In other words, it can be seen that, when a temperature change rate of the asymmetric bulk acoustic wave resonator as in the related art is 100%, a temperature change rate of the bulk acoustic wave resonators S1 and S2 according to an example embodiment in the present disclosure is 82% when the same power is applied. Accordingly, the amount of movement of the notch fs due to power may be suppressed to reduce the 2nd harmonic and IMD peak.

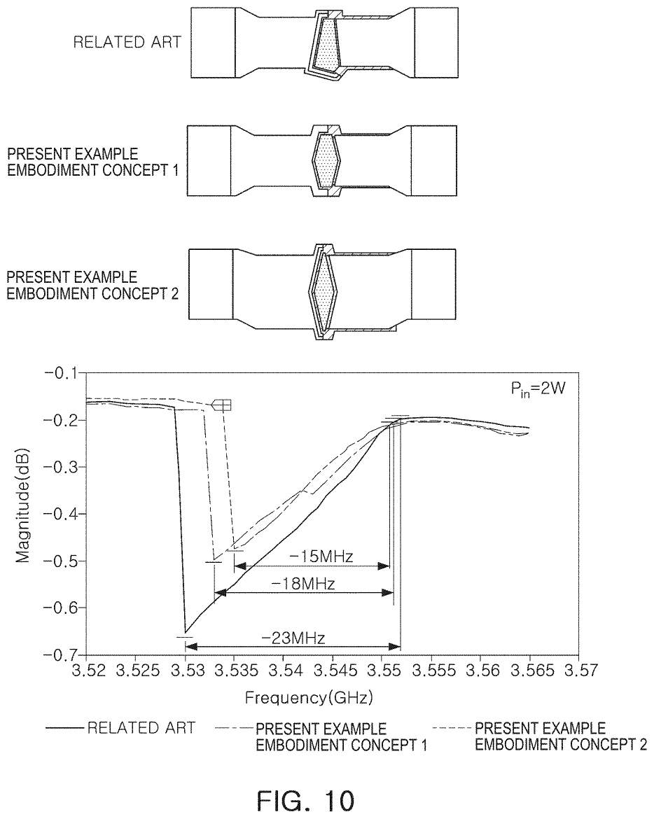

Meanwhile, since the bulk acoustic wave resonators S1 and S2 according to an example embodiment in the present disclosure have an aspect ratio AR of 5 or less, the amount of movement of notch fs due to power may be suppressed as illustrated in FIG. 10, compared with the related art. Furthermore, if the aspect ratio AR is increased, a heat dissipation path may be increased and the amount of movement of the notch fs due to power may be more suppressed due to the improvement of the insertion loss (IL) characteristic. Accordingly, the 2nd harmonic and IMD peak may be reduced.

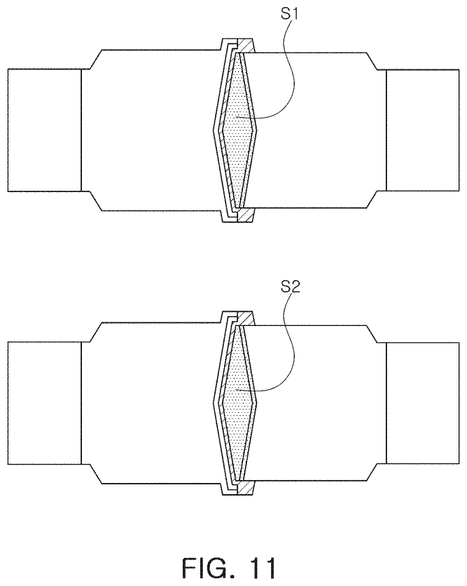

FIG. 11 is a schematic plan view illustrating a modified example embodiment of a bulk acoustic wave resonator having an anti-parallel structure disposed in portions A and B of FIG. 1.

Referring to FIG. 11, in the bulk acoustic wave resonators S1 and S2 according to one or more other example embodiments in the present disclosure, an active region may have an axisymmetric polygonal shape when viewed from above. As an example, in the bulk acoustic wave resonators S1 and S2 according to an example embodiment in the present disclosure, the active region may have an axisymmetric hexagonal shape when viewed from above. In addition, the bulk acoustic wave resonators S1 and S2 according to an example embodiment in the present disclosure may have an axisymmetric polygonal shape in which the active regions have the same aspect ratio (AR) when viewed from above. Meanwhile, in the bulk acoustic wave resonators S1 and S2 according to an example embodiment in the present disclosure, the aspect ratio AR may have a value between 5 and 10.

As such, since the bulk acoustic wave resonators S1 and S2 have an aspect ratio AR of 5 to 10, insertion loss IL performance may be improved and heat dissipation characteristics may be improved. Accordingly, a temperature increase due to power may be improved. In addition, when the insertion loss (IL) performance is improved, power loss consumed by the bulk acoustic wave resonators S1 and S2 may be reduced, and thus, the amount of self-heating may be reduced.

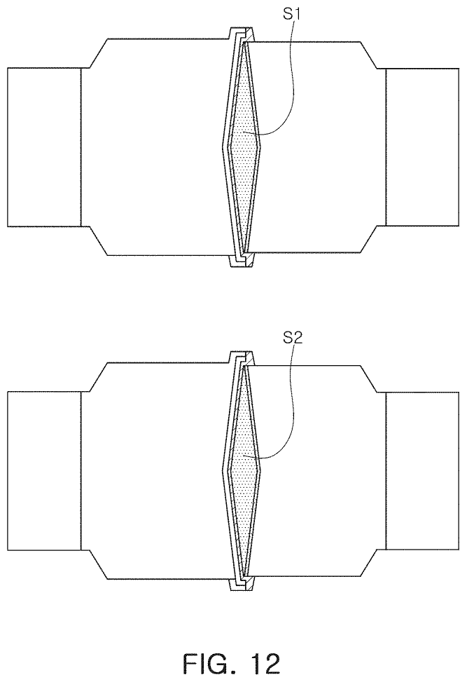

FIG. 12 is a schematic plan view illustrating a modified example embodiment of a bulk acoustic wave resonator having an anti-parallel structure disposed in portions A and B of FIG. 1.

Referring to FIG. 12, in the bulk acoustic wave resonators S1 and S2 according to one or more other example embodiments in the present disclosure, an active region may have an axisymmetric polygonal shape when viewed from above. As an example, in the bulk acoustic wave resonators S1 and S2 according to an example embodiment in the present disclosure, the active region may have an axisymmetric hexagonal shape when viewed from above. In addition, the bulk acoustic wave resonators S1 and S2 according to an example embodiment in the present disclosure may have an axisymmetric polygonal shape in which the active regions have the same aspect ratio (AR) when viewed from above. Meanwhile, in the bulk acoustic wave resonators S1 and S2 according to an example embodiment in the present disclosure, the aspect ratio AR may have a value of 10 or greater.

Accordingly, 2nd harmonic and IMD characteristics may be improved even in a spurious noise (S/N) interval. Furthermore, the 2nd harmonic and IMD peak may be reduced by suppressing the amount of movement of the notch (fs) due to power.

As set forth above, according to the present disclosure, a second harmonic peak may be reduced.

While specific example embodiments have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave filter comprising:
a plurality of series resonators connected to a series arm; and
a plurality of parallel resonators connected to a parallel arm connected to the series arm,
wherein at least two of the plurality of series resonators are disposed in parallel on the series arm, and
wherein the two series resonators disposed in parallel each comprises:
a substrate;
a lower electrode disposed on the substrate;
a piezoelectric layer covering at least a portion of the lower electrode; and
an upper electrode covering at least a portion of the piezoelectric layer,
wherein,
when an active region in which the lower electrode, the piezoelectric layer, and the upper electrode are all arranged to overlap each other is viewed from above, a centroid of the active region and a center of a rectangle defining an aspect ratio of the active region match each other, and
when the active region is viewed from above, the active region has a shape of a polygon symmetrical with respect to at least one axis passing through the center of the rectangle defining the aspect ratio.

2. The bulk acoustic wave filter of claim 1, wherein the rectangle defining the aspect ratio is a rectangle having a largest value of the aspect ratio.

3. The bulk acoustic wave filter of claim 1, wherein the polygon is an N-polygon, N≥4, and N is an even number.

4. The bulk acoustic wave filter of claim 1, wherein the aspect ratio of the active region has a value of 5 or less.

5. The bulk acoustic wave filter of claim 1, wherein the pair of series resonators has the same aspect ratio of the active region.

6. The bulk acoustic wave filter of claim 1, wherein the aspect ratio of the active region has a value ranging from 5 to 10.

7. The bulk acoustic wave filter of claim 1, wherein the aspect ratio of the active region has a value of 10 or greater.

8. The bulk acoustic wave filter of claim 1, further comprising a membrane layer forming a cavity together with the substrate.

9. The bulk acoustic wave filter of claim 8, further comprising an etch stop portion disposed to surround the cavity.

10. The bulk acoustic wave filter of claim 9, further comprising a sacrificial layer disposed outside of the etch stop portion.

11. The bulk acoustic wave filter of claim 1, further comprising an insertion layer at least partially disposed between the lower electrode and the piezoelectric layer.

12. The bulk acoustic wave filter of claim 1, further comprising a passivation layer disposed to expose a portion of each of the lower electrode and the upper electrode.

13. The bulk acoustic wave filter of claim 12, further comprising a metal pad in contact with the portions of the lower electrode and the upper electrode exposed from the passivation layer.

14. A bulk acoustic wave filter comprising:
a plurality of series resonators connected to a series arm; and
a plurality of parallel resonators connected to a parallel arm connected to the series arm,
wherein at least two of the plurality of series resonators are disposed in parallel and spaced apart from each other,
wherein the two series resonators disposed in parallel each comprises:
a substrate;
a lower electrode disposed on the substrate;
a piezoelectric layer covering at least a portion of the lower electrode; and
an upper electrode covering at least a portion of the piezoelectric layer,
wherein,
when an active region in which the lower electrode, the piezoelectric layer, and the upper electrode are all arranged to overlap each other is viewed from above, a centroid of the active region and a center of a rectangle defining an aspect ratio of the active region match each other, and
when the active region is viewed from above, the active region has a shape of a polygon symmetrical with respect to at least one axis passing through the center of the rectangle defining the aspect ratio.

15. A bulk acoustic wave filter comprising:
a plurality of series resonators connected to a series arm; and
a plurality of parallel resonators connected to a parallel arm connected to the series arm,
wherein at least two of the plurality of series resonators are disposed in parallel, and
wherein the two series resonators disposed in parallel each comprises:
a bulk acoustic wave resonator comprising an axisymmetric polygonal shaped active region when viewed from above, and when a smallest rectangle is drawn that contains the axisymmetric polygon, a longest side of the rectangle is h, a shortest side of the rectangle is b, and an aspect ratio is h/b.

16. The bulk acoustic wave filter of claim 15, wherein the axisymmetric polygonal shaped active region has two lines of symmetry perpendicular to each other when viewed from above.

17. The bulk acoustic wave filter of claim 15, wherein the bulk acoustic wave resonator comprises:
a substrate;
a lower electrode disposed on the substrate;
a piezoelectric layer covering at least a portion of the lower electrode; and
an upper electrode covering at least a portion of the piezoelectric layer,
wherein the lower electrode, the piezoelectric layer, and the upper electrode are all arranged to overlap each other in the active region.

18. The bulk acoustic wave filter of claim 15, wherein a centroid of the active region and a center of the rectangle match each other.

19. The bulk acoustic wave filter of claim 15, wherein the aspect ratio is greater than 5 and less than 10.

20. The bulk acoustic wave filter of claim 15, wherein the aspect ratio is greater than or equal to 10.

21. The bulk acoustic wave filter of claim 15, wherein the at least two of the plurality of series resonators disposed in parallel comprise at least one pair connected to a beginning of the series arm, at least one pair connected to an end of the series arm, or at least one pair connected to the beginning and one pair connected to the end of the series arm.

22. The bulk acoustic wave filter of claim 21, wherein the at least two of the plurality of series resonators disposed in parallel in each pair are connected to each other in an anti-parallel structure.
